(19) United States
(12) Patent Application Publication
(10) Pub. No.: US 2009/0205955 A1
(43) Pub. Date: Aug. 20, 2009

(54) METHOD OF MANUFACTURING A ROTATABLE SPUTTER TARGET

(75) Inventors: Anneleen De Smet, Kruishoutem (BE); Hugo Lievens, Gent (BE)

Correspondence Address: FOLEY AND LARDNER LLP;SUITE 500, 3000 K STREET NW, WASHINGTON, DC, 20007, US

(73) Assignee: NV BEKAERT SA

(21) Appl. No.: 12/303,421

(22) PCT Filed: May 31, 2007
(86) PCT No.: PCT/EP2007/055279

§ 371 Date: Dec. 4, 2008

(30) Foreign Application Priority Data
Jun. 26, 2006 (EP) 06116054.5

(51) Int. Cl. C23C 14/34; B28B 3/02

(52) U.S. Cl. 204/298.12; 264/319

(57) ABSTRACT

The invention relates to a method to manufacture a rotatable sputter target. The method comprises the steps of—providing a backing tube;—providing a target material on the backing tube by coiling at least one elongated member around the backing tube;—providing an outer material on top of the target material;—applying heat and/or pressure to the outer material and/or to the backing tube;—removing the outer material.

### FIELD OF THE INVENTION

The invention relates to a method of manufacturing a rotatable sputter target.

### BACKGROUND OF THE INVENTION

The use of sputter targets to deposit coatings such as metal coatings or ceramic coatings on large area substrates such as glass or elongated flexible substrates is well-known in the art.

A sputter target such as a rotatable sputter target can be manufactured by a number of different methods as for example by spraying, casting or isostatic pressing of powder. Isostatic pressing processes may comprise cold isostatic pressing (CIP), warm isostatic pressing (WIP) or hot isostatic pressing (HIP).

In the isostatic pressing processes known in the art, powder is poured between a backing tube and an outer can, the powder is dehumidified and/or degassed under a vacuum of for example 10⁻³ bar and the space between the backing tube and the outer can is sealed for example by vacuum welding.
In the isostatic pressing unit, pressure and/or temperature are increased at a predefined rate to the needed processing values. During a predefined time period, the hold-time, both parameters are kept constant. Finally, temperature and/or pressure are decreased at a certain rate until the isostatic pressing unit can be opened. After the isostatic pressing step the outer can is removed by grinding and the densified powder comes available at the outer surface.

Although hot isostatic pressing of powders allows to densify the target material, hot isostatic pressing of powders shows a number of drawbacks.

First of all, as this process requires working with fine powder, this raises health and safety issues.
Secondly, as a high flowability of the powder is needed to efficiently fill the gap between the backing tube and the outer can, the powders have to meet specific requirements.

Furthermore, the tapping density that can be obtained by using powders is often too low to obtain a sputter target with a target material having the required density.

Additionally, it is difficult or even impossible to obtain powder of some type of materials such as complex alloys.
Furthermore, to obtain the dehumidification and/or degassing of the powders before the application of the isostatic pressure long dehumidifying and/or degassing times are necessary.

### SUMMARY OF THE INVENTION

It is an object of the invention to avoid the drawbacks of the prior art. It is another object of the invention to provide a method of manufacturing a rotatable target having a dense target material. It is a further object of the present invention to provide a method giving a high flexibility in choosing the starting materials for the target material.

According to a first aspect of the present invention a method to manufacture a rotatable sputter target is provided. The method comprises the steps of
providing a backing tube;
providing a target material on the backing tube by coiling at least one elongated member around the backing tube;
providing an outer material on top of the target material;
applying heat and/or pressure to the outer material and/or to the backing tube;
removing the outer material.

Preferably, the target material is dehumidified and/or degassed before the application of heat and/or pressure.

The backing tube may comprise any type of backing tube known in the art. Preferably, the backing tube comprises a hollow cylindrical tube.

Preferred backing tubes are made of steel such as stainless steel, titanium, copper or aluminium.

The elongated member is coiled around the backing tube in such a way that the density of the coiled elongated member is preferably higher than 50%.

More preferably, the density of the coiled elongated member is higher than 70%, as for example between 78 and 92%.

For the purpose of this invention, with density is meant the volumetric density (% vol) of the target material after coiling of the elongated member around the backing tube and before the application of heat and/or pressure.

The density is calculated as follows

$$\frac{\begin{matrix}volume of the target material \\ coiled around the target base\end{matrix}}{\begin{matrix}volume of the gap between the \\ target base and the outer material\end{matrix}} \times 100 \%$$

A great advantage of the method according to the present invention is the high density of the target material obtained by coiling of the elongated member before the application of heat and/or pressure. The density obtained by the coiling of the elongated member is much higher than the tapping density that usually is obtained by pouring powders.

The outer material can be applied by any technique known in the art. The outer material comprises for example a tubular body that is placed around the target material.

In a preferred embodiment the outer material comprises a cylindrical shaped body made of a metal or metal alloy.
In an alternative embodiment the outer material comprises a flexible material made of a polymer material such as PVC or rubber. The size of the inner diameter of the outer material is preferably adapted to the outer diameter of the backing tube provided with the target material.

By the application of heat and/or pressure to the outer material and/or to the backing tube, the target material is densified.

Preferably, the application of heat and/or pressure comprises isostatic pressing such as hot isostatic pressing (HIP), warm isostatic pressing (WIP) or cold isostatic pressing (CIP).
In a hot isostatic pressing process the temperature is preferably between 300 and 2000° C. In a warm isostatic pressing process the temperature is preferably between ambient temperature and 300° C. In a cold isostatic pressing process the temperature is not increased by external application of heat and is equal to ambient temperature at the start.

A great advantage of the method of the present invention is the high flexibility in choosing the starting materials and consequently the high number of different types of rotatable sputter targets that can be manufactured.

Another important advantage of the method of the present invention is the high homogeneity of the target material that is obtained.

The homogeneity of the target material of a sputter target according to the present invention is much higher than the target material of sputter targets obtained by methods known in the art such as casting or isostatic pressing of powders.

An elongated member used for the manufacturing of a target according to the present invention may comprise any material. The main requirement of the elongated member is that it can be coiled around the target base.

The elongated member may for example comprise a ceramic, a metal, a metal alloy or a combination of these materials, such as an elongated metal member coated with a ceramic material, or a metal tube filled with ceramic particles, such as powder particles.

Preferred metals and metal alloys comprise for example molybdenum, niobium, indium, tantalum, zinc, tin, osmium, zirconium, tungsten, iron and alloys thereof.

Preferred metal alloys comprise stainless steel, zinc-tin alloys, and copper alloys.
Preferred ceramics comprise metal oxides such as zinc oxide, tin oxide, indium oxide, indium tin oxide,

An elongated member can have any cross-section such as a circular cross-section or a rectangular cross-section.

In principle any type of elongated member can be considered. The elongated member may for example comprise a monofilament, a multifilament, a combination of monofilaments, a combination of multifilaments or a combination of monofilaments and multifilaments.

With monofilament is meant any kind of wire, tape or strip, such as a metal wire, metal tape or metal strip.

With multifilament is meant any structure comprising a number of monofilaments, for example any twisted, bundled, knitted or braided structure of monofilaments. The individual monofilaments of a multifilament can be identical or can be different. The individual monofilaments of a multifilament can for example have the same diameter and/or the same composition or can have a different diameter and/or a different composition.

With a combination of monofilaments is meant any possible combination of at least two monofilaments such as a combination of monofilaments having a different diameter and/or a combination of monofilaments having a different cross-section and/or a combination of monofilaments having a different composition.

An example of a combination of monofilaments comprises a zinc monofilament with a diameter of 1 mm and a tin monofilament with a diameter of 1 mm.

If more than one monofilament is coiled around the target base, the monofilaments can be coiled individually in consecutive steps or the monofilaments can be coiled together in one step.

With a combination of multifilaments is meant any possible combination of at least two multifilaments such as a combination of multifilaments having a different structure and/or a combination of multifilaments having a different composition.

An example of such a combination comprises a stainless steel multifilament comprising 3 core filaments and 9 outer filaments, each filament having a diameter of 0.24 mm (3+9*0.24).

With a combination of monofilaments and multifilaments is meant any possible combination of at least one monofilament with at least one multifilament.

An example comprises a combination of a zinc monofilament with a diameter of 1 mm and a stainless steel multifilament comprising 3 core filaments and 9 outer filaments, each filament having a diameter of 0.24 mm.

An elongated member may also comprise a hybrid material as for example a coated wire, tape or strip or a tube filled with particles Examples of a hybrid materials comprise a molybdenum wire coated with a zinc coating, a zinc wire coated with a tin coating, or a hollow metal tube filled with metal oxide powder particles.

An elongated member can be chosen within a broad diameter range as long as the elongated member can be coiled around the target base. Preferably, the elongated member has a diameter within the range of 0.2 to 5 mm as for example a diameter of 1 mm.

The smaller the diameter of the elongated member, the higher the starting density of the target material.

The number of layers coiled around the backing tube can be chosen within any range.

The more layers of elongated members, the higher the starting density of the target material.
Preferably, the number of layers coiled around the backing tube ranges between 1 and 10 is for example 4.

According to a second aspect of the present invention a rotatable sputter target is provided. The rotatable sputter target is obtainable by the above-mentioned method.

### BRIEF DESCRIPTION OF THE DRAWINGS

The invention will now be described into more detail with reference to the accompanying drawings wherein

FIG. 1 is an illustration of a method according to the present invention.

### DESCRIPTION OF THE PREFERRED EMBODIMENTS OF THE INVENTION

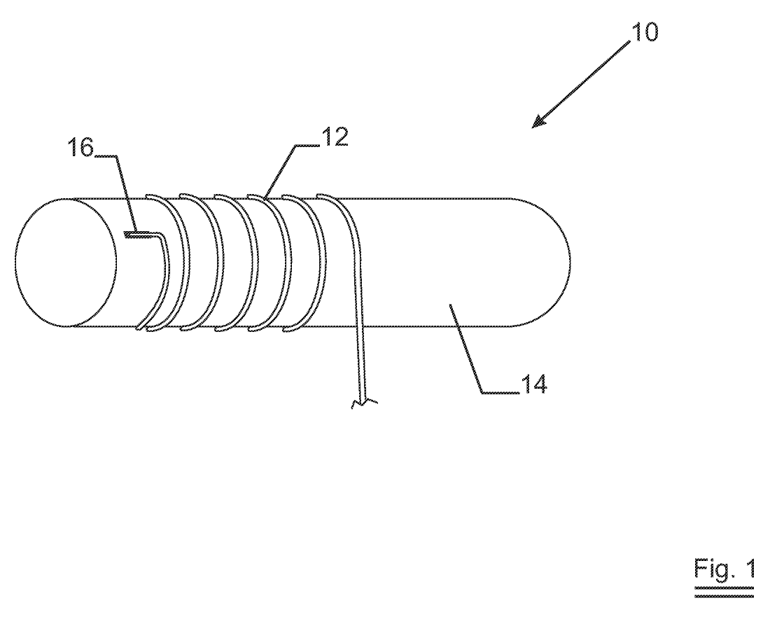

The process to manufacture a rotatable sputter target 10 according to the present invention is further illustrated in FIG. 1.

A molybdenum wire 12 (99.95 % purity) having a diameter of 1 mm is coiled around a backing tube 14 of stainless steel.

Because of the great difference in thermal expansion coefficient of stainless steel and molybdenum, it can be preferred to apply one or more intermediate layers on the backing tube before the application of the molybdenum wire.
The intermediate layer or layers has preferably a thermal expansion coefficient that is lower than the thermal expansion coefficient of the backing tube but higher than the thermal expansion coefficient of the target material.

Before the start of the coiling, the metal wire is fixed to the backing tube. The fixation of the metal wire can be done by any technique known in the art. Preferably, the fixation of the metal wire is done mechanically for example by means of a screw or a clip. Also an adhesive can be used to fix the metal wire.

It is preferred that the way of fixation has no influence on the outer diameter of the target material and does not create a local increase in the thickness of the target material.
A preferred way is by providing a groove 16 in the backing tube 14 and by clamping the metal wire 12 in this groove 16. It can be preferred to subject the part of the metal wire that will be clamped in the groove to a thermal treatment.

The number of layers coiled around the backing tube is for example 3.

After the coiling the metal wire is fixed to the backing tube in a similar way as described above at the start of the coiling.

An outer can is prepared. A hole is drilled at a well-defined position of the outer can to weld a degassing tube. The degassing tube is preferably positioned above the groove of the backing tube to assure there is a good channel towards the area to be degassed and to avoid bending during the isostatic pressing of the welded zone.

It can be preferred to apply a coating such as a boron nitride coating on the outer can to facilitate removal of the outer can after HIP.

The thus prepared sputter target is introduced in a HIP unit and is subjected to the following HIP cycle.

The temperature is increased at a heating rate of at the most 8° C. per minute till a temperature of 1130° C. (±10° C.).

The pressure is increased with increasing temperature till a pressure of 1000 bar (±50 bar) is obtained.

A pressure of 1000 bar (±50 bar) is applied during 120 minutes. During this time period, the temperature is maintained at a temperature of 1130° C. (±10° C.).
Subsequently, the sputter target is cooled at a cooling rate lower than 8° C. per minute and the HIP unit is opened if the temperature is below 150° C.

Finally, the outer material is removed for example by grinding and the target material comes available at the outer surface.

1. A method to manufacture a rotatable sputter target, said method comprising the steps of
providing a backing tube;
providing a target material on said backing tube by coiling at least one elongated member around said backing tube;
providing an outer material on top of said target material;
applying heat and/or pressure to said outer material and/or to said backing tube;
removing said outer material.

2. A method according to claim 1, whereby said coiled elongated member before the application of heat and/or pressure has a density of at least 70%.

3. A method according to claim 1, whereby the step of applying heat and/or pressure to said target material comprises isostatic pressing such as hot isostatic pressing, warm isostatic pressing or cold isostatic pressing.

4. A method according to claim 1, whereby the elongated metal member comprises a ceramic, a metal, a metal alloy or a combination thereof.

5. A method according to claim 1, whereby said elongated member comprises a monofilament, a multifilament, a combination of monofilaments, a combination of multifilaments or a combination of monofilaments and multifilaments.

6. A method according to claim 5, whereby said monofilament comprises a wire, a tape or a strip.

7. A method according to claim 5, claims, whereby said monofilament comprises a coated wire, a coated tape or a coated strip.

8. A method according to claim 5, whereby said monofilament comprises a wire having a diameter ranging between 0.2 and 5 mm.

9. A method according to claim 5, whereby said multifilament comprises a twisted, bundled or braided structure of monofilaments.

10. A rotatable sputter target obtainable by the method as described in claim 1.
